(19) United States
(12) Patent Application Publication
(10) Pub. No.: US 2026/0206535 A1
(43) Pub. Date: Jul. 16, 2026

(54) TRANSFER HEAD AND SEMICONDUCTOR MANUFACTURING APPARATUS INCLUDING THE SAME

(71) Applicant: Samsung Electronics Co., Ltd., Suwon-si (KR)

(72) Inventors: GYUNAM KIM, Suwon-si (KR); DAEHYUN KIM, Suwon-si (KR); YOUNGAN SONG, Suwon-si (KR); SUNGYONG LEE, Suwon-si (KR); YUNHWAN HWANG, Suwon-si (KR)

(21) Appl. No.: 19/436,433

(22) Filed: Dec. 30, 2025

(30) Foreign Application Priority Data
Jan. 16, 2025 (KR) 10-2025-0006936

(51) Int. Cl. H10P 72/30; H10P 72/00

(52) U.S. Cl. CPC H10P 72/3308; H10P 72/0416; H10P 72/3302

(57) ABSTRACT

A transfer head includes a horizontal body extending in a first direction, vertical arms connected to opposite peripheral portions of the horizontal body, respectively, the vertical arms extending in parallel to each other in a second direction perpendicular to the first direction, and each of the vertical arms having a side surface facing inward, and graspers connected to lower ends of the vertical arms, respectively, and the graspers configured to hold a substrate. Each of the vertical arms has a thickness in a third direction perpendicular to the first and second directions, and, for each vertical arm of the vertical arms, the thickness in the third direction decreases in a direction extending from an inner surface of the vertical arm to an outer surface of the vertical arm.

### CROSS-REFERENCE TO RELATED APPLICATIONS

This application claims priority under 35 U.S.C. § 119 to Korean Patent Application No. 10-2025-0006936 filed on January 16, 2025, in the Korean Intellectual Property Office, the disclosures of which are incorporated by reference herein in their entireties.

### BACKGROUND

Embodiments of the present disclosure described herein relate to a transfer head and a semiconductor manufacturing apparatus including the same.

Semiconductor devices are manufactured by using various semiconductor manufacturing apparatuses. For example, a transfer apparatus for semiconductor devices may be used in a process of manufacturing semiconductor devices. The transfer apparatus may transfer semiconductor devices, such as a semiconductor chip, or a precursor to a semiconductor device, such as a substrate, to a required position between process operations. For example, in order to transfer a semiconductor substrate to a required location during a cleaning process, the transfer apparatus may include a transfer head. The transfer head may be used to pick up a semiconductor substrate that is immersed by a cleaning liquid in a cleaning vessel and transfer the semiconductor substrate to another location.

Cleaning residues that may remain with the transfer head may flow down to the semiconductor substrate and reversely contaminate the semiconductor substrate when semiconductor substrates are picked up using the transfer head. Accordingly, a change in the structure of the transfer head may be beneficial.

### SUMMARY

Embodiments of the present disclosure provide a transfer head that may prevent reverse contamination of a semiconductor substrate, and a semiconductor manufacturing apparatus including the same.

According to an embodiment, a transfer head includes a horizontal body extending in a first direction, vertical arms connected to opposite peripheral portions of the horizontal body, respectively, the vertical arms extending in parallel to each other in a second direction perpendicular to the first direction, and each of the vertical arms have a side surface facing inward, and graspers connected to lower ends of the vertical arms, respectively, and the graspers configured to hold a substrate, each vertical arm of the vertical arms has a thickness in a third direction perpendicular to the first and second directions, and the thickness in the third direction of the vertical arm decreases in a direction extending from an inner surface of the vertical arm to an outer surface of the vertical arm.

According to an embodiment, a transfer head includes a horizontal body extending in a first direction, vertical arms connected to opposite peripheral portions of the horizontal body, respectively, the vertical arms extending in parallel to each other in a second direction perpendicular to the first direction, and each of the vertical arms having a side surface facing inward, and graspers connected to lower ends of the vertical arms, respectively, and the graspers configured to hold a substrate, a lower end portion of each of the vertical arms has a first thickness in a third direction perpendicular to the first and second directions, an upper end portion of each of the graspers has a second thickness in the third direction, the second thickness is greater than the first thickness, and, for each grasper of the graspers, an upper surface of the grasper has a downward inclination from an inner surface of the grasper toward an outer surface of the grasper.

According to an embodiment, a semiconductor manufacturing apparatus includes a transfer head configured to hold a substrate, a horizontal arm connected to an upper end of the transfer head, a vertical driving shaft connected to a first side of the horizontal arm, and the vertical driving shaft configured to move in a first direction, a second direction perpendicular to the first direction, and a third direction perpendicular to the first and second directions, and a first cleaning module that hold a cleaning liquid, the transfer head includes a horizontal body extending in the first direction, vertical arms connected to opposite peripheral portions of the horizontal body, respectively, the vertical arms extending in parallel to each other in the second direction, and each of the vertical arms having a side surface facing inward, and graspers connected to lower ends of the vertical arms, respectively, and configured to accommodate a substrate, each of the vertical arms has a thickness in the third direction, and, for each vertical arm of the vertical arms, the thickness of the vertical arm in the third direction decreases in a direction extending from an inner surface of the vertical arm to an outer surface of the vertical arm.

### BRIEF DESCRIPTION OF THE FIGURES

The above and other objects and features of the present disclosure will become apparent by describing in detail embodiments thereof with reference to the accompanying drawings.

FIG. 1 is a cross-sectional view of a transfer head according to an embodiment of the present disclosure.

FIG. 2 is a side view illustrating area “X” of FIG. 1.

FIG. 3 is an enlarged perspective view illustrating area “Y” of FIG. 1.

FIG. 4 is a cross-sectional view taken along lines A-A′ and B-B′ of FIG. 3.

FIG. 5 illustrates a transfer head according to an embodiment of the present disclosure, and is an enlarged perspective view corresponding to area “Y” of FIG. 1.

FIG. 6 is a cross-sectional view taken along line B-B’ of FIG. 5.

FIG. 7 illustrates a transfer head according to an embodiment of the present disclosure, and is an enlarged perspective view corresponding to area “Y” of FIG. 1.

FIG. 8 is a cross-sectional view taken along line C-C’ of FIG. 7.

FIG. 9 is an enlarged perspective view illustrating area “Z” of FIG. 1.

FIG. 10 illustrates a transfer head according to an embodiment of the present disclosure, and is a side view corresponding to area “X” of FIG. 1.

FIG. 11A illustrates a transfer head according to an embodiment of the present disclosure, and is an enlarged perspective view corresponding to area “Z” of FIG. 1.

FIG. 11B is a cross-sectional view illustrating a transfer head that holds a substrate according to an embodiment of the present disclosure.

FIG. 12 is an exploded cross-sectional view of a transfer head according to an embodiment of the present disclosure.

FIG. 13 is an enlarged perspective view illustrating area “V” of FIG. 12.

FIG. 14 is a cross-sectional view of a semiconductor manufacturing apparatus according to an embodiment of the present disclosure.

FIG. 15 is a cross-sectional view of a semiconductor manufacturing apparatus according to an embodiment of the present disclosure.

FIG. 16 is a side view of a semiconductor manufacturing apparatus according to an embodiment of the present disclosure.

FIG. 17 is a side view of a semiconductor manufacturing apparatus according to an embodiment of the present disclosure.

FIGS. 18A and 18B are cross-sectional views illustrating operation processes of a semiconductor manufacturing apparatus according to an embodiment of the present disclosure.

### DETAILED DESCRIPTION

Hereinafter, embodiments of the present disclosure will be described with reference to the accompanying drawings. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such.

Throughout the specification, when a component is described as "including" a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact. As the state of contact is binary (either in contact or not in contact), it will be appreciated that “contact” has the same scope as any use of “direct contact.”

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

As used herein, the phrase “integrally connected” may refer to a structures or components that are formed together as a single body without a break in the continuity of the material of which they are formed. For example, there may be no discernable interface between the structures or components, and the labels of the structures and components may serve to identify portions of the single body rather than discrete structures or components.

The term "substrate" may denote a base substrate (e.g., an initial semiconductor substrate forming the base of the wafer in the final wafer product, such as a bulk semiconductor substrate (e.g., formed of crystalline silicon), a silicon on insulator (SOI) substrate, etc.), or a stack structure including such a base substrate and layers formed on the base substrate.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

In the following description, spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

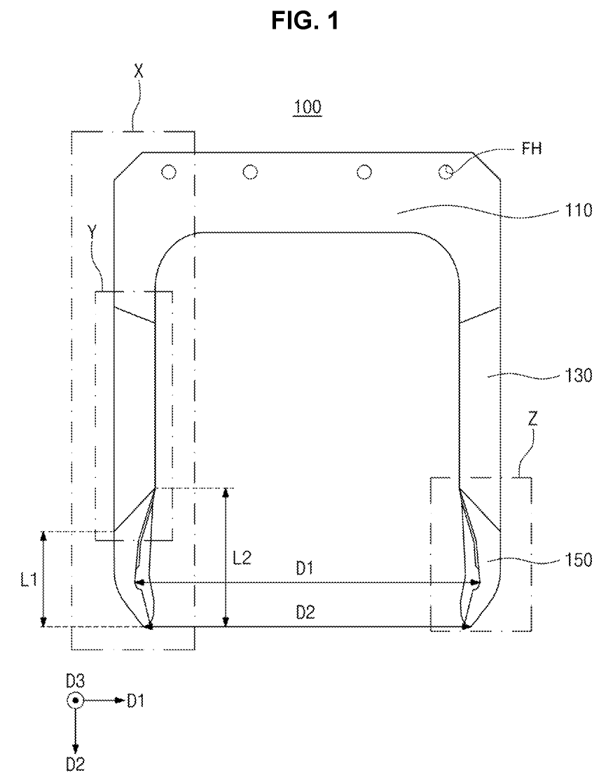

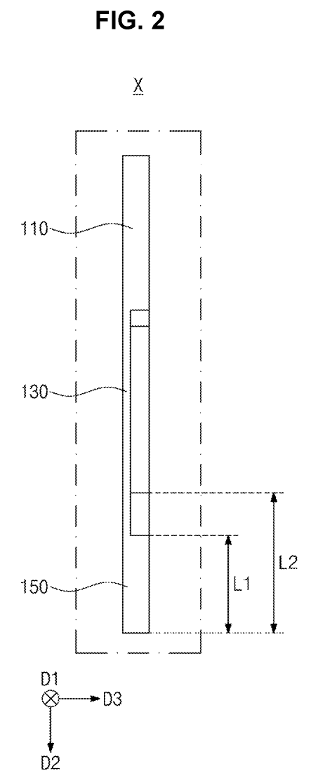

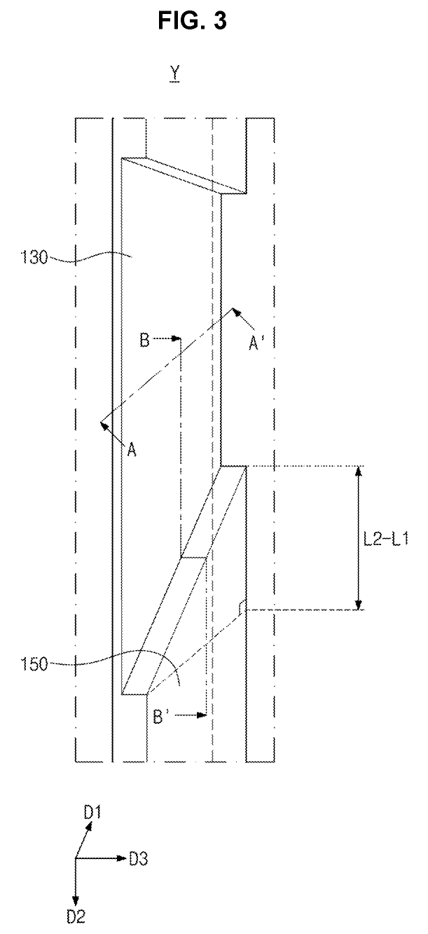

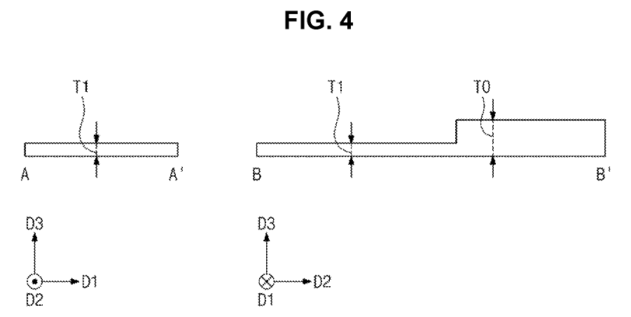

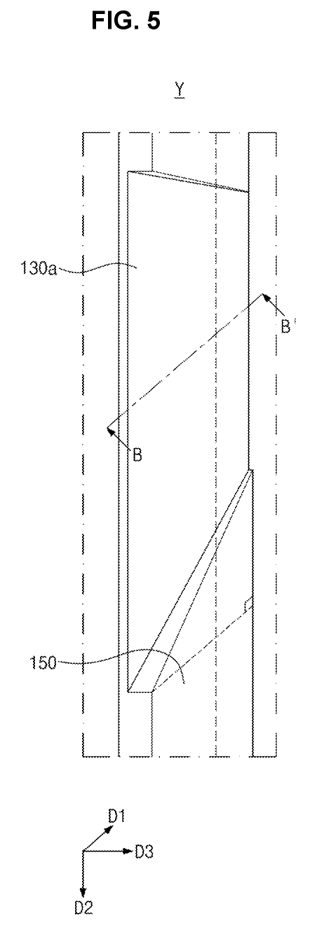

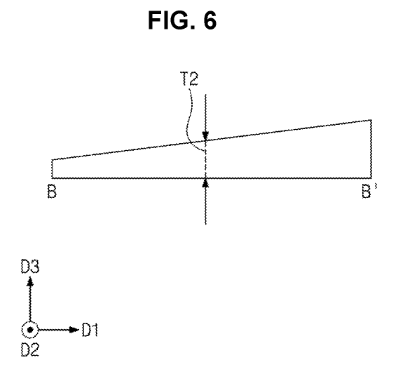

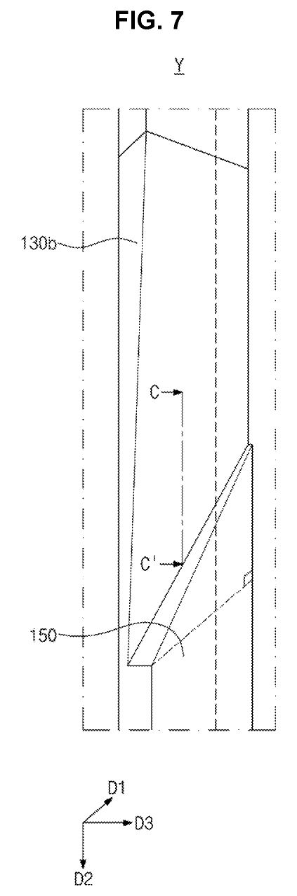

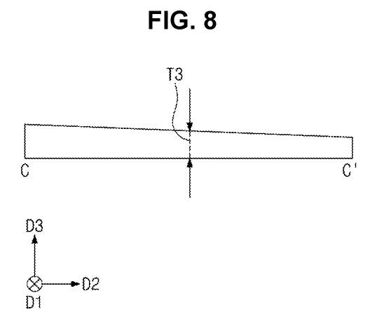

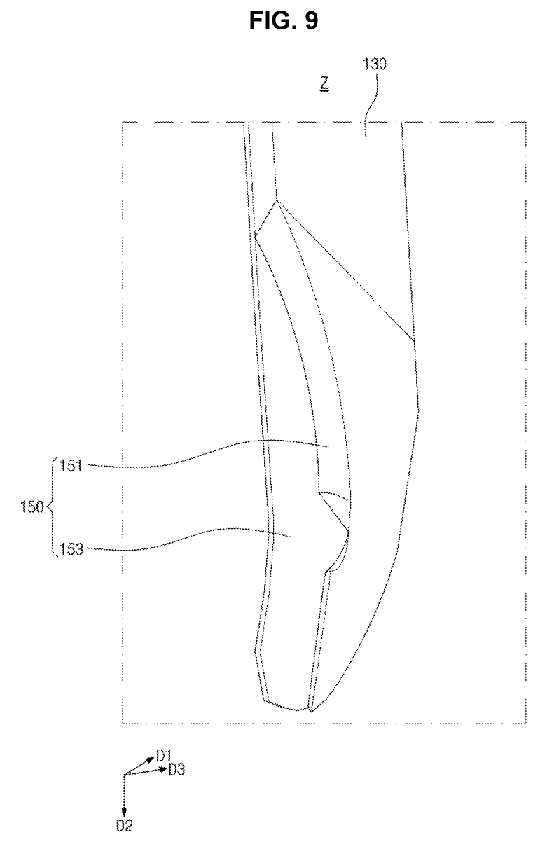

FIG. 1 is a front view of a transfer head according to an embodiment of the present disclosure. FIG. 2 is a side view illustrating area “X” of FIG. 1. FIG. 3 is an enlarged perspective view illustrating area “Y” of FIG. 1. FIG. 4 is a cross-sectional view taken along lines A-A′ and B-B′ of FIG. 3. FIG. 5 illustrates a transfer head according to an embodiment of the present disclosure, and is an enlarged perspective view corresponding to area “Y” of FIG. 1. FIG. 6 is a cross-sectional view taken along line B-B’ of FIG. 5. FIG. 7 illustrates a transfer head according to an embodiment of the present disclosure, and is an enlarged perspective view corresponding to area “Y” of FIG. 1. FIG. 8 is a cross-sectional view taken along line C-C’ of FIG. 7. FIG. 9 is an enlarged perspective view illustrating area “Z” of FIG. 1.

Referring to FIGS. 1 to 9, a transfer head 100 according to an embodiment of the present disclosure may include a horizontal body 110, vertical arms 130, and graspers 150.

The transfer head according to an embodiment of the present disclosure may be a head unit of a transfer device that transfers semiconductor substrates between process operations of a semiconductor manufacturing process. The transfer device may hold a semiconductor substrate using the transfer head. The semiconductor substrate may include a silicon-on-insulator (SOI) substrate, a metal substrate, a glass substrate, a plastic substrate, or the like. The semiconductor substrate, for example, may be a silicon substrate, a germanium substrate, or a silicon-germanium substrate. Details of the transfer head will be described below, and details of the semiconductor manufacturing apparatus including the transfer head will be described later.

The horizontal body 110 may extend lengthwise in a first direction D1. The horizontal body 110 may be a structure that extends in the first direction D1 as a whole. The horizontal body 110 may have a bar shape. For example, as illustrated in FIG. 1, the horizontal body 110 may have a bar shape having a length in the first direction D1 and a width in a second direction D2 that is perpendicular to the first direction D1.

A lower surface of the horizontal body 110 may be a flat surface. Opposite peripheral portions of an upper end of the horizontal body 110 may have a diagonal shape. For example, the horizontal body 110 may have a hexagonal bar shape, of which a lower surface is flat and of which opposite peripheral portions of an upper end between a side surface and an upper surface have a diagonal shape.

Furthermore, the horizontal body 110 may have a rectangular shape having a uniform thickness when viewed from a lateral side. For example, the horizontal body 110 may have a rectangular shape, of which a thickness in a third direction D3 that is perpendicular to the first and second directions D1 and D2 as illustrated in FIG. 2 is constant, and that extends in the second direction D2 when viewed from a lateral side. In the following description, terms such as upper and lower will be in reference to the third direction D3.

The horizontal body 110 may be formed of a material having excellent heat resistance, chemical resistance, wear resistance, and lightweight. For example, the horizontal body 110 may include polyether ether ketone (PEEK).

The horizontal body 110 may have a plurality of fastening holes FH formed therein. The fastening holes FH may be formed at an upper portion of the horizontal body 110. For example, as illustrated in FIG. 1, four fastening holes FH may be formed in an upper portion of the horizontal body 110 side by side in the first direction D1. The number of fastening holes FH is not limited thereto, and various numbers of fastening holes FH may be provided.

The vertical arms 130 may be connected to opposite peripheral portions of the horizontal body 110, respectively. For example, one vertical arm 130 may be connected to a lower surface of a first peripheral portion of the horizontal body 110, and another vertical arm 130 may be connected to a lower surface of a second peripheral portion of the horizontal body 110 opposite the first peripheral portion. For example, two vertical arms 130 may each be connected to a lower surface of the horizontal body 110.

The vertical arms 130 may extend lengthwise in the second direction D2. The vertical arms 130 may be provided as structures having side surfaces that face each other, respectively, and may extend parallel to each other in the second direction D2 (e.g., the side surfaces may face inward, towards the center of the transfer head 100. For example, the vertical arms 130 may extend parallel to each other in the second direction D2 from opposite peripheral portions of the horizontal body 110.

In an embodiment, the vertical arms 130 may be integrally connected to the horizontal body 110 (e.g., there may not be a material discontinuity between the vertical arms 130 and the horizontal body 110). The vertical arms 130 may be formed of the same or substantially the same material as that of the horizontal body 110. For example, the vertical arms 130 may include polyether ether ketone (PEEK).

In an embodiment, a thickness of each of the vertical arms 130 in the third direction D3 may decrease in a direction extending from an inner surface to an outer surface of the vertical arms 130. Here, the inner surface may be a side surface in a direction that the vertical arms 130 face one another, and the outer surface may be a side surface that faces away from the inner surface. For example, as illustrated in FIGS. 5 and 6, a thickness T2 of the vertical arm 130 in the third direction D3 may decrease towards an opposite direction to the first direction D1. In this case, the vertical arm 130 illustrated in FIG. 5 may correspond to the vertical arm 130 that is present on a left side of the transfer head 100 illustrated in FIG. 1.

Because the thickness T2 of the vertical arm 130 in the third direction D3 decreases from the inner surface to the outer surface of the vertical arm 130, the vertical arm 130 may have an inclined side surface (hereinafter, referred to as an inclined surface).

In an embodiment, a minimum thickness of an intermediate portion of the vertical arm 130 in the third direction D3 may be greater than a minimum thickness of a lower end portion of the vertical arm 130 in the third direction D3. For example, as illustrated in FIGS. 7 and 8, a thickness T3 of the vertical arm 130 in the third direction D3 may gradually decrease from the intermediate portion to the lower end portion. For example, the vertical arm 130 may have an inclined surface that is inclined from an inner upper end to an outer lower end thereof (e.g., the inclined surface may be inclined in the first direction D1 and the second direction D2).

The graspers 150 may be connected to lower ends of the vertical arms 130, respectively. For example, the graspers 150 may be structures that extend in the second direction D2 from the lower ends of the vertical arms 130.

An upper surface of each of the graspers 150 may have a downward inclination from an inner surface of the grasper 150 toward an outer surface of the grasper 150. For example, a distance from a lowermost end of the grasper 150 to an upper surface of the grasper 150 may decrease in a direction from the inner surface of the grasper 150 towards the outer surface of the grasper 150. For example, as illustrated in FIGS. 1 and 2, a distance L2 from the lowermost end of the grasper 150 to a portion of the upper surface of the grasper 150 that forms an edge with the inner surface of the grasper 150, may be greater than a distance L1 from the lowermost end of the grasper 150 to a portion of the upper surface of the grasper 150 that forms an edge with the outer surface of the grasper 150. For example, L1 may be smaller than L2.

Each of the graspers 150 may include a holding portion 151 and a support portion 153. The holding portion 151 may have a holding surface. The holding surface may be an inner surface of the holding portion 151 having a shape corresponding to a periphery of a substrate “W”. The holding surface may correspond to a portion of the periphery of the substrate “W”. For example, the holding surface may have a curved surface. The holding portion 151 may hold the substrate “W” through the holding surface.

The support portion 153 may extend from one side portion of the holding portion 151. For example, the support portion 153 may protrude from the holding surface of the holding portion 151 and extend in the second direction D2 and may have a planar support surface perpendicular to the third direction D3. A distance in the first direction D1 between opposing support portions 153 that face one another, which may be referred to as a spacing distance, may be smaller than a diameter of the substrate “W”. Accordingly, the support portion 153 may support the substrate “W” so that the substrate “W” held by the holding portion 151 is prevented from deviating (e.g., a support surface of the support portion 153 may support an outer portion of a planar surface of the substrate such at a top or bottom surface).

In an embodiment, a maximum distance between the holding surfaces of the facing graspers 150 may be greater than a diameter of the substrate “W”. Furthermore, a distance between the lowermost ends of the facing graspers 150 may be smaller than the diameter of the substrate “W”. As illustrated in FIG. 1, a maximum spacing distance D1 between the holding surfaces of the graspers 150 may be greater than the diameter of the substrate “W”, and a spacing distance D2 between the lowermost ends of the graspers 150 may be smaller than the diameter of the substrate “W”. Accordingly, the graspers 150 may hold the substrate “W”. Furthermore, the holding surface above may substantially contact the portion of the periphery of the substrate “W”. Accordingly, the holding surface of the holding portion 151 may completely hold the substrate “W”.

In an embodiment, the facing graspers 150 may accommodate the substrate “W” in a vertical direction (e.g., may hold the substrate “W” in a vertical direction with the top and bottom surfaces of the substrate being vertical. Here, the vertical direction may refer to the second direction D2. For example, the holding portions 151 may hold the substrate “W” in the vertical direction, and the support portions 153 may support the substrate “W” in the vertical direction.

In an embodiment, the graspers 150 may be integrally connected to the vertical arms 130, respectively. Furthermore, the graspers 150 may be formed of substantially the same material as that of the horizontal body 110 and the vertical arms 130. For example, the graspers 150 may include polyether ether ketone (PEEK).

In an embodiment, the horizontal body 110, the vertical arms 130, and the graspers 150 may be integrally connected to each other. The horizontal body 110, the vertical arms 130, and the graspers 150 may be integrally connected to each other to form an inverted “U” shape.

In an embodiment, each vertical arm 130 may have a step difference from the grasper 150 to which it is directly connected. For example, a lower end portion of each of the vertical arms 130 may have a first thickness in the third direction D3, an upper end part of each of the graspers 150 may have a second thickness in the third direction D3, and the second thickness may be greater than the first thickness. For example, as illustrated in FIGS. 3 and 4, a thickness T1 of the lower end portion of the vertical arm 130 in the third direction D3 may be smaller than a thickness T0 of the upper end portion of the grasper 150 in the third direction D3.

Furthermore, a maximum thickness of each of the graspers 150 in the third direction D3 may be greater than a thickness of the vertical arm 130 in the third direction D3. For example, as illustrated in FIGS. 3 and 4, the maximum thickness T0 of the grasper 150 in the third direction D3 may be greater than the thickness T1 of the vertical arm 130 in the third direction.

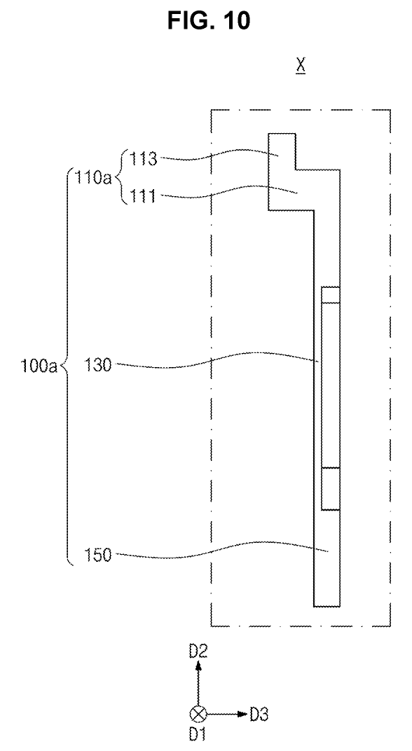

FIG. 10 illustrates a transfer head according to an embodiment of the present disclosure, and is a side view corresponding to area “X” of FIG. 1.

Referring to FIG. 10, the horizontal body 110a may include a lower plate 111 and a vertical plate 113. The lower plate 111 may extend in the first direction D1. When viewed in a plan view, the lower plate 111 may have a rectangular shape. For example, the lower plate 111 may have a bar shape that has a length in the first direction D1 and has a width in the third direction D3.

The vertical plate 113 may be connected to the lower plate 111. For example, the vertical plate 113 may extend upward from an upper surface of the lower plate 111. For example, the vertical plate 113 may extend upward from an upper surface of a first peripheral portion of the lower plate 111. For example, as illustrated in FIG. 10, the vertical plate 113 may extend from an upper surface of a peripheral portion of the lower plate 111 in an opposite direction to the third direction D3, among the peripheral portions of the lower plate 111.

In an embodiment, because the horizontal body 110a includes the vertical plate 113 and the lower plate 111, the horizontal body 110a may have an “L” shape when viewed from a lateral side. For example, the horizontal body 110a may include the vertical plate 113 that extends in the second direction D2 and the lower plate 111 having a width in the third direction D3 on a lower surface of the vertical plate 113, and may have an “L” shape as illustrated in FIG. 10.

In an embodiment, the vertical plate 113 may be integrally connected to the lower plate 111. For example, the vertical plate 113 may be formed of substantially the same material as that of the lower plate 111 and there may be no discontinuity between the vertical plate 113 and the lower plate 111.

In an embodiment, the vertical arms 130 may be connected to the lower plate 111. For example, the vertical arms 130 may extend downward from a lower surface of the lower plate 111. For example, the vertical arms 130 may extend downward from a lower surface of second peripheral portion of the lower plate 111, which is opposite to the first peripheral portion. For example, as illustrated in FIG. 10, the vertical arms 130 may extend from a lower surface of a peripheral portion of the lower plate 111 that is peripheral in the third direction D3, among the peripheral portions of the lower plate 111, and may extend in the opposite direction to the second direction D2.

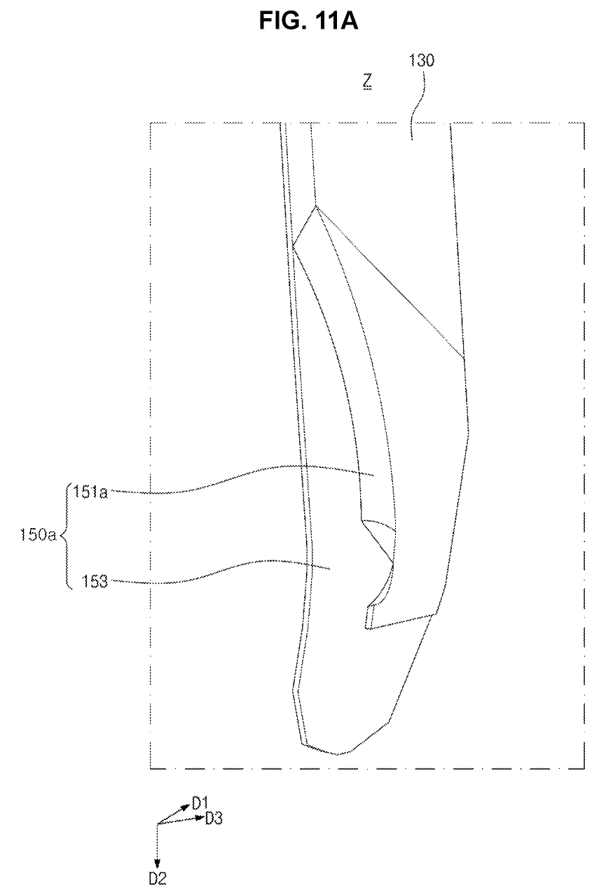

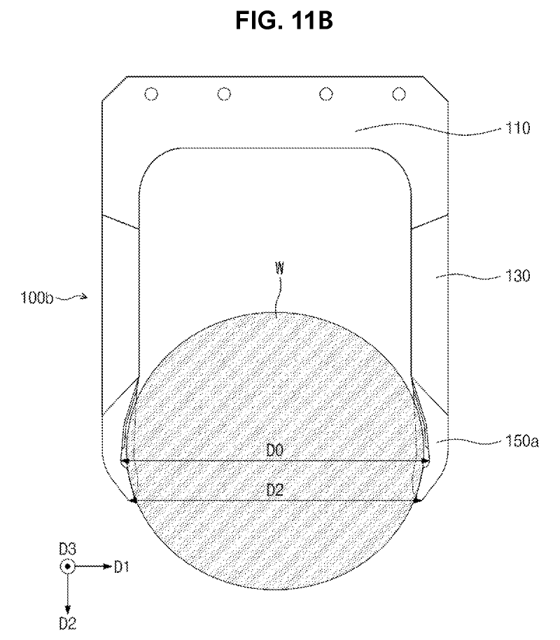

FIG. 11A illustrates a transfer head according to an embodiment of the present disclosure, and is an enlarged perspective view corresponding to area “Z” of FIG. 1. FIG. 11B is a cross-sectional view illustrating a transfer head that holds a substrate according to an embodiment of the present disclosure.

Referring to FIGS. 11A and 11B, the grasper 150a may include a holding portion 151a and a support portion 153, and a lower end of the holding portion 151a may be higher than a lower end of the support portion 153 relative to the lower end of the grasper 150a. For example, a level of a lower end of the holding portion 151a may be located at a higher level than a level of a lower end of the support portion 153 relative to the lower end of the grasper 150a. For example, unlike the illustration in FIG. 9, the holding portion 151a may have a shape that is similar to the holding portion 151 of FIG. 9, but in which a lower end portion of a holding portion is omitted (compare to FIG. 9).

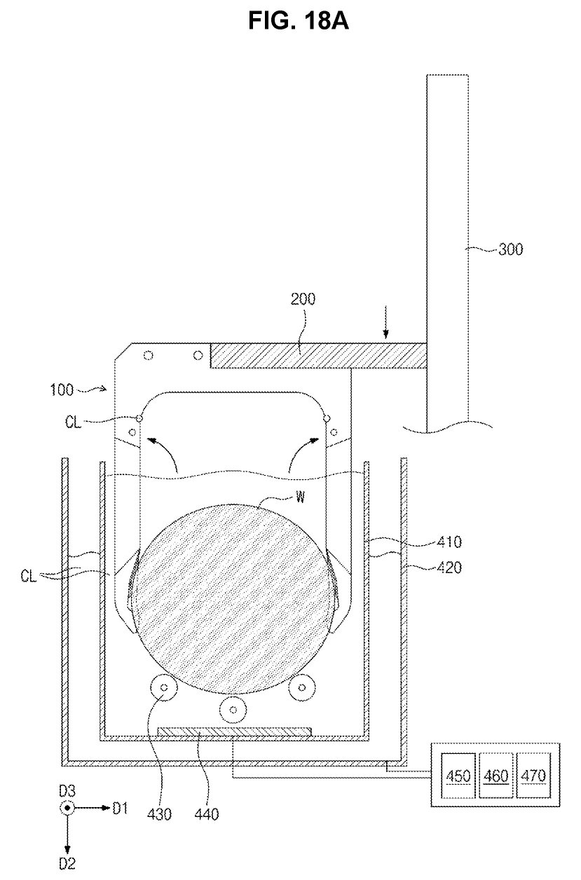

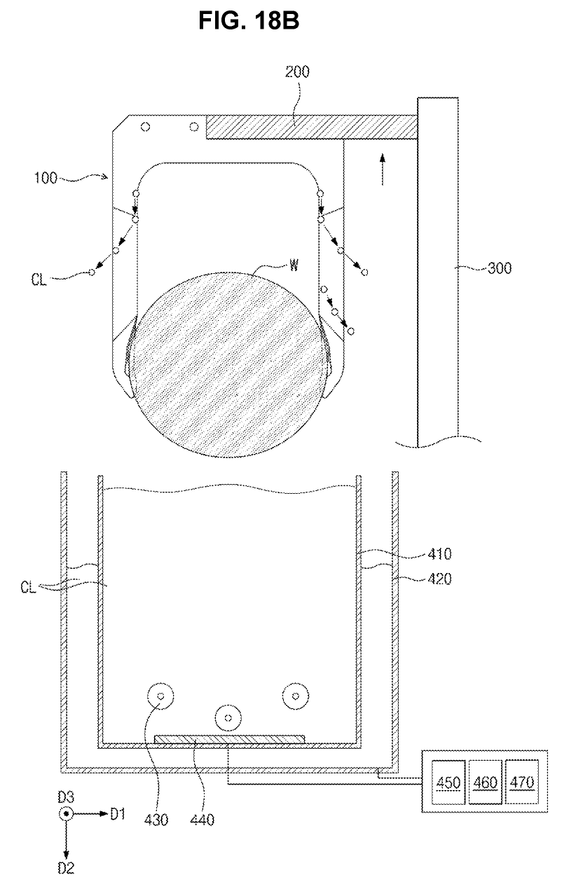

In an embodiment, a distance D2 between lowermost ends of the facing holding portions 151a may be smaller than a diameter D0 of the substrate “W”. Accordingly, as illustrated in FIG. 11B, the holding portions 151a may accommodate the substrate “W” between one another. The level of the lower ends of the holding portions 151a are located at a higher level than the level of the lower ends of the support portion 153, so that in an operation process of a semiconductor manufacturing apparatus 10 (see FIG. 18B) that will be described later, the cleaning residues (e.g., the cleaning liquids CL (see FIG. 18B)) that reside in the graspers 150a may flow out to spaces between the holding portions 151a and the support portions 153. As a result, the graspers 150a of the transfer head 100b may prevent reverse contamination of the substrate “W” due to the cleaning residues.

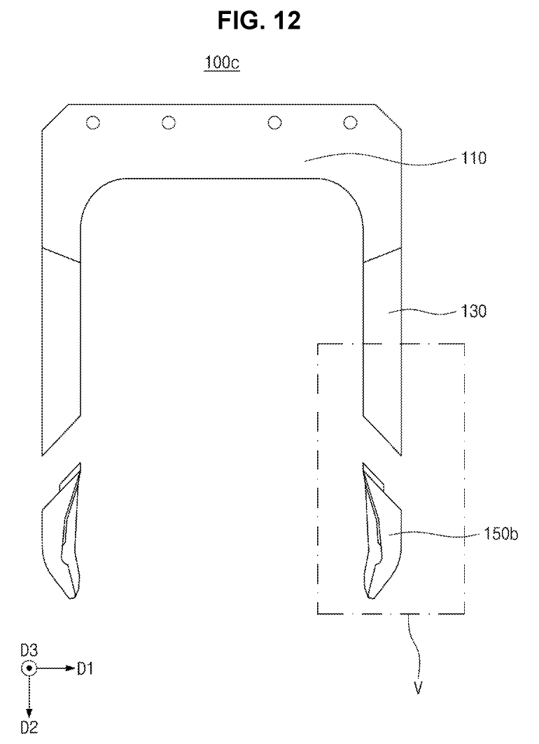

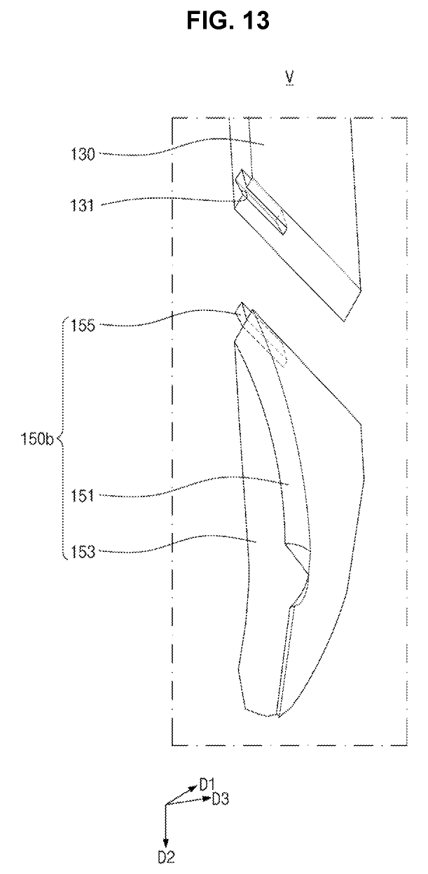

FIG. 12 is an exploded cross-sectional view of a transfer head according to an embodiment of the present disclosure. FIG. 13 is an enlarged perspective view illustrating area “V” of FIG. 12.

Referring to FIGS. 12 and 13, the grasper 150 may be detachable from the vertical arm 130. For example, the grasper 150 may be mounted on and demounted from the vertical arm 130 and may have a diagonal interface. Unlike this, for example, the grasper 150 may be mounted on and demounted from the vertical arm 130 in a diagonal direction.

As illustrated in FIG. 13, the vertical arm 130 may have a recess 131, and the accommodation part may include a protrusion 155. The recess 131 may be recessed upward from a lower surface of the vertical arm 130. Furthermore, the recess 131 may extend from the inner surface of the vertical arm 130 toward the outer surface of the vertical arm 130. Furthermore, the recess 131 may be spaced apart from the outer surface of the vertical arm 130.

For example, the recess 131 may have a pair of opposite side surfaces that extend in a lengthwise direction of the recess 131 and an end side surface that extends in a widthwise direction of the recess 131. One side of the recess 131, which faces a short side surface may be open. For example, the short side surface of the recess 131 may be spaced apart from the outer surface of the vertical arm 130.

The protrusion 155 may protrude from an upper surface of the grasper 150. For example, the protrusion 155 may protrude from the upper surface of the grasper 150 in an opposite direction to the second direction D2. The protrusion 155 may extend from an inner surface of the grasper 150 toward an outer surface of the grasper 150. Furthermore, the protrusion 155 may be spaced apart from the outer surface of the grasper 150.

In an embodiment, a shape of the protrusion 155 may correspond to a shape of an interior space of the recess 131. For example, the protrusion 155 may have a cross-sectional profile matching a cross-sectional profile of the recess 131. The protrusion 155 may be undersized relative to the recess 131 to aid in removing the protrusion 155 from the recess 131. The grasper 150 may be coupled to the vertical arm 130 by fixing the protrusion 155 in the recess 131. For example, the grasper 150 and the vertical arm 130 may be coupled to each other and separated from each other through the fitment of the protrusion 155 in the recess 131. Accordingly, the transfer head 100c may be maintained by decoupling the grasper 150 from the vertical arm 130 and replacing the grasper 150 with a new grasper 150. As a result, a durability of the transfer head 100c may be increased.

The semiconductor manufacturing apparatus including the transfer head according to an embodiment of the present disclosure will be described below.

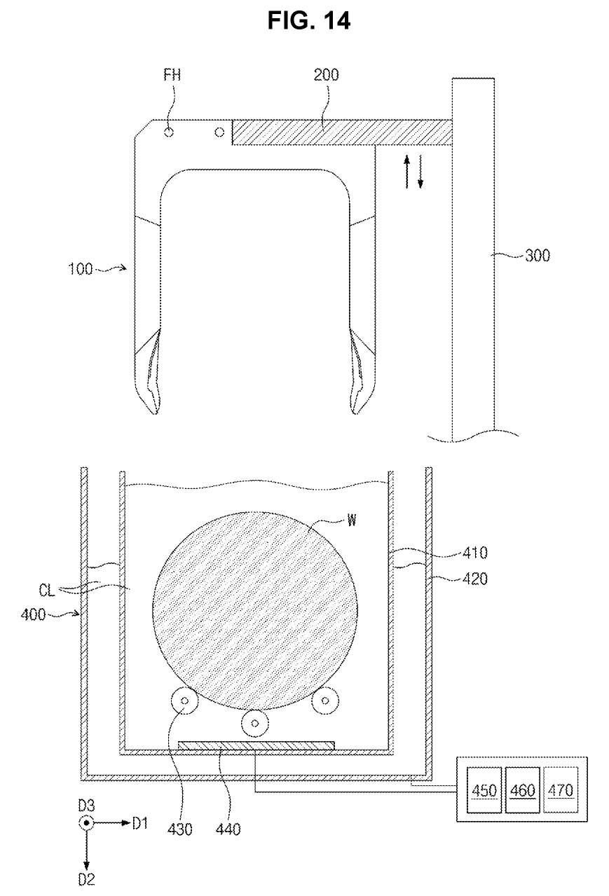

FIG. 14 is a cross-sectional view of a semiconductor manufacturing apparatus according to an embodiment of the present disclosure. For convenience of description, descriptions of features that are the same or substantially the same as those described previously may not be duplicated and the following description will primarily relate to differences from the above-described embodiments.

Referring to FIG. 14, the semiconductor manufacturing apparatus 10 according to an embodiment of the present disclosure may include a transfer head 100, a horizontal arm 200, a vertical driving shaft 300, and a first cleaning module 400.

The transfer head 100 may hold the substrate “W” as described previously. The transfer head 100 may hold the substrate “W” in the semiconductor manufacturing apparatus 10 and transfer it to another location, such as from a carrier to a cleaning module. The transfer head 100 illustrated in FIG. 14 may be substantially the same as the transfer heads 100, 100a, 100b, and 100c described above in FIGS. 1 to 13.

The horizontal arm 200 may be connected to an upper end of the transfer head 100. The horizontal arm 200 may extend in the first direction D1. For example, the horizontal arm 200 may be connected to the transfer head 100 through fastening holes FH of the transfer head 100. For example, the horizontal arm 200 may be coupled to the fastening holes FH of the transfer head 100 through separate screws or bolts. Accordingly, the horizontal arm 200 may fix the transfer head 100.

The horizontal arm 200 may be moved in a horizontal direction and a vertical direction by the vertical driving shaft 300. For example, the horizontal arm 200 may be moved in the first direction D1 and a direction opposite to the first direction D1. For example, the horizontal arm 200 may be moved in the second direction D2 and a direction opposite to the second direction D2. For example, the horizontal arm 200 may be moved in the third direction D3 and a direction opposite to the third direction D3.

The horizontal arm 200 may have a rectangular parallelepiped shape having a length in the first direction D1. For example, the horizontal arm 200 may have a rod shape that extends in the first direction D1.

The vertical driving shaft 300 may be connected to the horizontal arm 200. For example, the vertical driving shaft 300 may be connected to a first side of the horizontal arm 200. For example, a first side of the vertical driving shaft 300 may be connected to an actuator for moving the vertical driving shaft. A second side of the vertical driving shaft, which is opposite to the first side, may support the horizontal arm 200 and the transfer head 100, which are connected to each other. The vertical driving shaft 300 may extend in the second direction D2.

The vertical driving shaft 300 may be moved in a horizontal direction and a vertical direction. For example, the vertical driving shaft 300 may be moved in the first direction D1 and a direction opposite to the first direction D1 by an actuator. For example, the vertical driving shaft 300 may be moved in the second direction D2 and direction opposite to the second direction D2. For example, the vertical driving shaft 300 may be moved in the third direction D3 and a direction opposite to the third direction D3. Through the movement of the vertical driving shaft 300, the horizontal arm 200 may be moved, and accordingly, the transfer head 100 may be moved and operated.

The vertical driving shaft 300 may have a rectangular parallelepiped shape having a length in the second direction D2. For example, the vertical driving shaft 300 may have a plate shape that extends in the second direction D2.

The first cleaning module 400 may store a cleaning liquid CL. For example, the first cleaning module 400 may be a module for cleaning the substrate “W” through the cleaning liquid CL. Here, the cleaning liquid CL may be a liquid material for cleaning the substrate “W”. For example, the cleaning liquid CL may be a material for removing residues on the substrate “W”, on which a photoresist process, a plasma etching process, or a chemical mechanical polishing process has been performed. The cleaning liquid CL, for example, may include an alkaline material, a polar organic solvent, a surfactant, a corrosion inhibitor, an additive, and the like. For example, the cleaning liquid CL may include hydroxylamine (NH₂OH), tetramethylammonium hydroxide (TMAH; C₄H₁₃NO), N-Methyl-2-Pyrrolidone (C₅H₉NO), dimethyl sulfoxide (C₂H₆OS), glycols, amino alcohols, or a combination thereof.

In an embodiment, the first cleaning module 400 may include a first cleaning vessel 410, a second cleaning vessel 420, an ultrasonic wave generator 440, a pump 450, a heater 460, and a filter 470. The first cleaning vessel 410 may store the cleaning liquid CL. When the process is performed, the first cleaning vessel 410 may accommodate the substrate “W” and the cleaning liquid CL so that the substrate “W” may be immersed in the cleaning liquid CL.

The first cleaning vessel 410 may have a structure in which an upper portion is open. For example, the first cleaning vessel 410 may have a rectangular parallelepiped structure with an upper surface having an opening. For example, an upper end of the first cleaning vessel 410 may be open or may have an upper surface with an opening into the first cleaning vessel 410. The first cleaning vessel 410 may receive the substrate “W” through the opening. The first cleaning vessel 410 may have a width and a height that is sufficient to accommodate the substrate “W” (e.g., sufficient that the entire substrate “W” may be immersed in the cleaning liquid CL).

The ultrasonic wave generator 440 may be provided inside the first cleaning vessel 410. For example, the ultrasonic wave generator 440 may be provided on a bottom surface of the first cleaning vessel 410. For example, the ultrasonic wave generator 440 may be disposed in a lower area of an interior space of the first cleaning vessel 410.

The ultrasonic wave generator 440 may generate ultrasonic waves. For example, the ultrasonic wave generator 440 may be a transducer that converts an electrical signal into ultrasonic energy. The ultrasonic wave generator 440 may deliver ultrasonic waves to the cleaning liquid CL stored in the first cleaning vessel 410. The cleaning liquid CL may vibrate from the ultrasonic waves, and when the process is performed, the substrate “W” may be cleaned while receiving the vibration. For example, the ultrasonic wave generator 440 may assist in cleaning the substrate “W” through generation of ultrasonic waves.

In an embodiment, the first cleaning module 400 may further include a roller 430. The roller 430 may be disposed in the lower area of the interior space of the first cleaning vessel 410. The roller 430 may be provided on and/or above the ultrasonic wave generator 440.

A plurality of rollers 430 may be provided. For example, as illustrated in FIG. 14, the first cleaning module 400 may include three rollers. The rollers 430 may rotate the substrate “W” when a cleaning process is performed. For example, the roller 430s may be rotated about a linear axis that is parallel to the third direction D3. Through the rotation of the roller 430, the substrate “W” may be rotated in parallel with a surface defined by the first and second directions D1 and D2 (e.g., parallel to the first and second directions D1 and D2). For example, the roller 430 may rotate the substrate “W” in a vertical orientation.

The second cleaning vessel 420 may accommodate the first cleaning vessel 410. The second cleaning vessel 420 may have a structure with an upper portion that is open. For example, the second cleaning vessel 420 may have a rectangular parallelepiped structure with an upper surface having an opening or the upper end of the second cleaning vessel may be open. For example, an upper end of the second cleaning vessel 420 may have an opening. The second cleaning vessel 420 may accommodate the first cleaning vessel 410 through the opening. A width of the second cleaning vessel 420 may be greater than a width of the first cleaning vessel 410. A height of the second cleaning vessel 420 may be greater than a height of the first cleaning vessel 410. For example, the second cleaning vessel 420 may have a width and a height that are sufficient enough to accommodate the first cleaning vessel 410.

The second cleaning vessel 420 may store the cleaning liquid CL that overflows from the first cleaning vessel 410. For example, when the cleaning process is performed, the second cleaning vessel 420 may accommodate the cleaning liquid CL that overflows from the first cleaning vessel 410 when the substrate “W” is cleaned and/or when the transfer head 100 holds/transfers the substrate “W”.

The pump 450 may be provided outside the second cleaning vessel 420. For example, the pump 450 may be provided on one side of the second cleaning vessel 420. The pump 450 may be connected to the first cleaning vessel 410 and the second cleaning vessel 420 through separate pipelines.

The pump 450 may supply the cleaning liquid CL to the first cleaning vessel 410. Furthermore, the pump 450 may receive the cleaning liquid CL that resides in the second cleaning vessel 420. For example, the pump 450 may supply the cleaning liquid CL to the first cleaning vessel 410 and receive the residual cleaning liquid CL used in the process from the second cleaning vessel 420 to circulate the cleaning liquid CL.

The heater 460 may be provided on the one side of the second cleaning vessel 420. The heater 460 may be connected to the pump 450. The heater 460 may heat the cleaning liquid CL passing through the pump 450.

For example, the heater 460 may provide heat to the cleaning liquid CL that circulates through the pump 450 to control the temperature of the cleaning liquid CL and keep the temperature uniform. The heater 460 may be provided in a pipeline that is connected between the pump 450 and the second cleaning vessel 420. For example, the heater 460 may be provided in a form of an n-line.

The filter 470 may be provided on the one side of the second cleaning vessel 420. The filter 470 may be connected to the pump 450. For example, the filter 470 may be provided in the pump 450. The filter 470 may filter the residual cleaning liquid CL supplied from the second cleaning vessel 420 to remove residual debris in the cleaning liquid CL. For example, as the cleaning process is performed, the cleaning liquid CL may remove residue debris on the substrate “W” from a surface of the substrate “W” which contaminates the cleaning liquid CL and the filter 470 may then remove contaminants in the cleaning liquid CL.

The filter 470, for example, may be disposed in a pipeline that is connected between the pump 450 and the first cleaning vessel 410. For example, the filter 470 may be provided in the form of an n-line. However, the present disclosure is not limited thereto, and the filter 470, for example, may be separately disposed between the pump 450 and the first cleaning vessel 410.

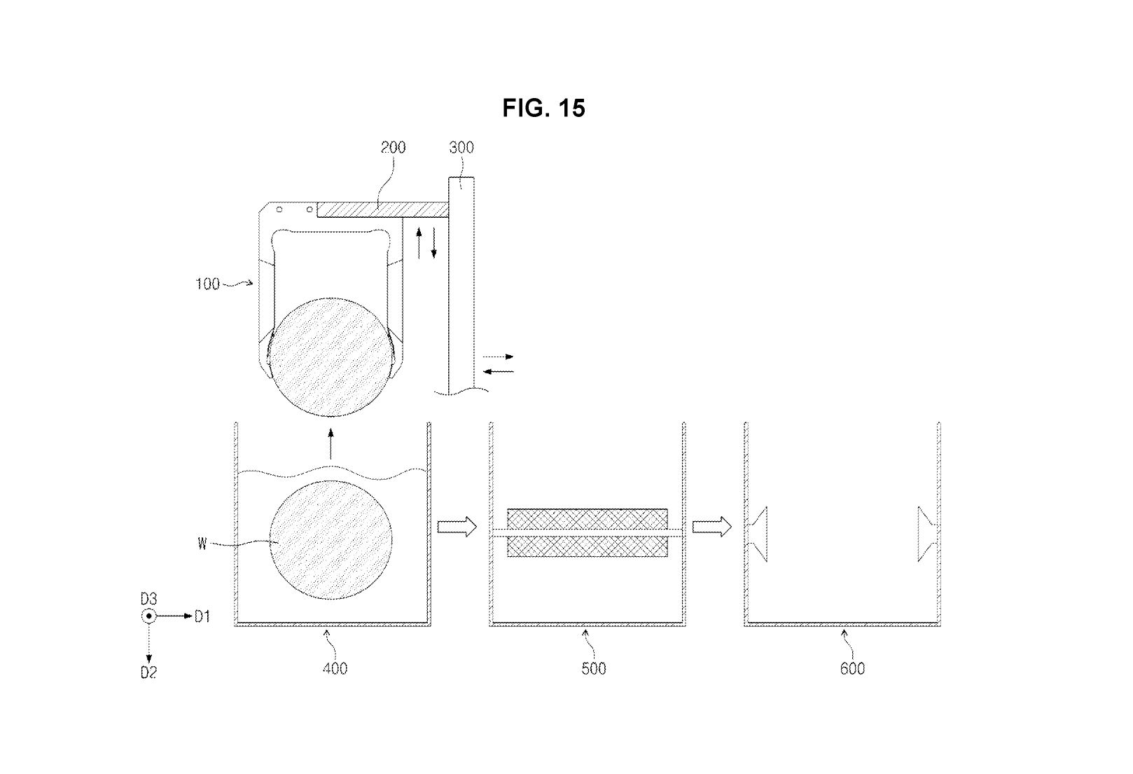

FIG. 15 is a cross-sectional view of a semiconductor manufacturing apparatus according to an embodiment of the present disclosure. For convenience of description, differences from the above-described embodiment will be mainly described hereinafter.

Referring to FIG. 15, the semiconductor manufacturing apparatus 10 according to an embodiment of the present disclosure may further include a second cleaning module 500 and a third cleaning module 600. The second cleaning module 500 may be provided on one side of the first cleaning module 400. The second cleaning module 500 may include a brush. The brush may be provided in the second cleaning module 500. For example, a plurality of brushes may be provided, and the substrate “W” may be brushed through rotation thereof.

For example, when the process is performed, the transfer head 100 may pick up the substrate “W” accommodated in the first cleaning module 400 and transfer it to the second cleaning module 500. Thereafter, the second cleaning module 500 may remove cleaning residues that are left on the substrate “W” that has been cleaned through the first cleaning module 400. For example, the brushes in the second cleaning module 500 may shake off the cleaning residues on the substrate “W” through rotation thereof.

The third cleaning module 600 may be provided on one side of the second cleaning module 500. The third cleaning module 600 may include a dryer. The dryer may be provided in the third cleaning module 600. A plurality of dryers may be provided.

For example, the third cleaning module 600 may dry the substrate “W” that has been cleaned through the first cleaning module 400 and/or the second cleaning module 500. For example, when the process is performed, the transfer head 100 may pick up the substrate “W” in the second cleaning module 500 and transfer it to the third cleaning module 600. Thereafter, the third cleaning module 600 may dry the substrate “W” that has been brushed through the second cleaning module 500.

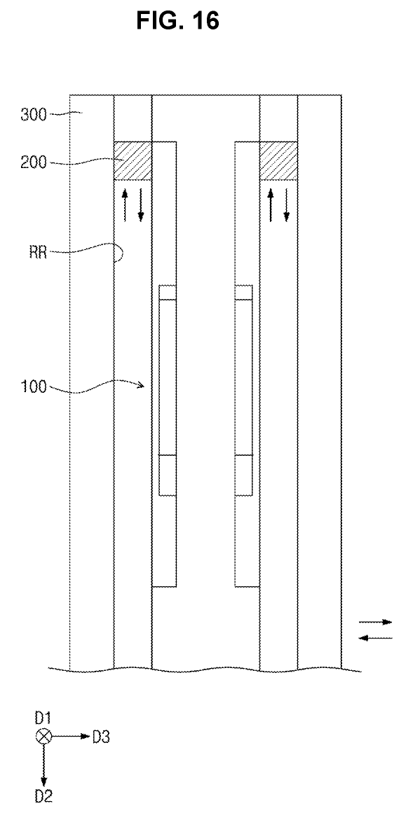

FIG. 16 is a side view of a semiconductor manufacturing apparatus according to an embodiment of the present disclosure.

Referring to FIG. 16, the semiconductor manufacturing apparatus 10 may include a plurality of transfer heads 100. For example, the semiconductor manufacturing apparatus 10 may include a plurality of horizontal arms 200, and the transfer heads 100 may be coupled to the horizontal arms 200, respectively.

For example, the vertical driving shaft 300 may include two recess rails RR. Each of the recess rails RR may be recessed from one side surface of the vertical driving shaft 300 in the first direction D1. Each of the recess rails RR may extend from one side surface of the vertical driving shaft 300 in the second direction D2. Horizontal arms 200 may be connected to peripheral portions of the recess rails RR. Accordingly, two horizontal arms 200 may be coupled to the vertical driving shaft 300. As the transfer heads 100 are coupled to the horizontal arms 200, respectively, the semiconductor manufacturing apparatus 10 may include two transfer heads 100.

Each of the transfer heads 100 may vertically move along the recess rail RR. For example, each of the transfer heads 100 may be moved in the second direction D1 and an opposite direction to the second direction D2 along the recess rail RR. Furthermore, the transfer heads 100 may be moved individually. Accordingly, the semiconductor manufacturing apparatus 10 may continuously pick up substrates “W” through the transfer heads 100.

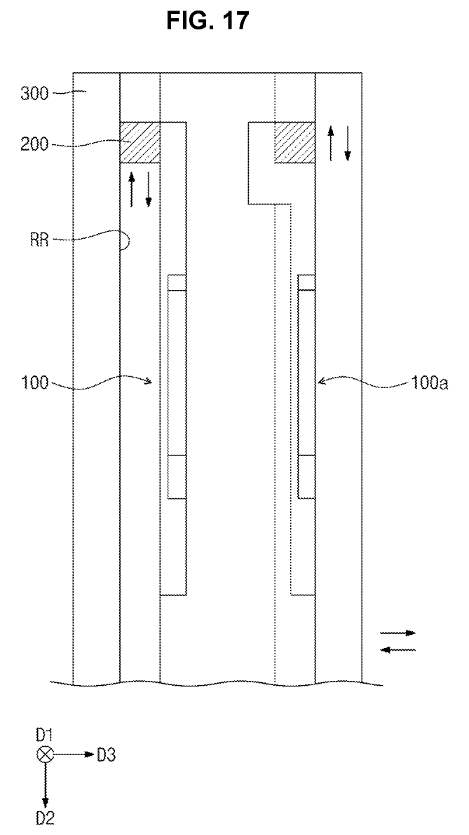

FIG. 17 is a side view of a semiconductor manufacturing apparatus according to an embodiment of the present disclosure.

Referring to FIG. 17, the semiconductor manufacturing apparatus 10 may include various types of transfer heads 100 and 100a. For example, the semiconductor manufacturing apparatus 10 may include a transfer head 100 (hereinafter, the first transfer head) illustrated in FIG. 1 and a second transfer head 100b (hereinafter, the second transfer head) illustrated in FIG. 10. The transfer heads 100 and 100b may be coupled to the horizontal arms 200, respectively.

For example, as illustrated in FIG. 17, the first transfer head 100 may be coupled to one side of the horizontal arm 200, and the second transfer head 100b may be coupled to an opposite side of another horizontal arm 200. For example, the first and second transfer heads 100 and 100b may be coupled to opposite side surfaces of the horizontal arms 200. In this case, the second transfer head 100b may have an “L” shape. Accordingly, a horizontal spacing distance between the transfer heads 100 and 100b in the third direction D3 may increase compared to that illustrated in FIG. 16. For example, an arrangement interval between the transfer heads 100 and 100b may increase. As a result, when the process is performed, a phenomenon in which pollutants splatter between the transfer heads 100 and 100b may be improved. Furthermore, a cleanliness of the process may be improved.

The operation processes of the semiconductor manufacturing apparatus according to an embodiment of the present disclosure will be described hereinafter.

FIGS. 18A and 18B are cross-sectional views illustrating operation processes of a semiconductor manufacturing apparatus according to an embodiment of the present disclosure.

Referring to FIGS. 18A and 18B, the substrate “W” may be accommodated in the first cleaning vessel 410. The cleaning liquid CL may be stored in the first cleaning vessel 410. The rollers 430 in the first cleaning vessel 410 may rotate the substrate “W”. The cleaning liquid CL may be vibrated by the ultrasonic wave generator 440. The substrate “W” may be cleaned due to the vibration of the cleaning liquid CL and the rotation of the substrate “W”.

Thereafter, the horizontal arm 200 may be lowered by the vertical driving shaft 300, and accordingly, the transfer head 100 may be lowered into the first cleaning vessel 410. The transfer head 100 may accommodate the substrate “W”, for example, through movement thereof in the second direction D2 and the third direction D3. As the substrate “W” is accommodated in the graspers 150 of the transfer head 100, the transfer head 100 may hold the substrate “W”. As illustrated in FIG. 18A, when the substrate “W” is held by the transfer head 100, the horizontal body 110 may not be immersed in the cleaning liquid CL of the first cleaning vessel 410. As the horizontal body 110 is not immersed in the cleaning liquid CL, reverse contamination of the substrate “W” due to the residual cleaning liquid CL that is present on the transfer head 100 may be prevented.

In an embodiment, when the transfer head 100 is lowered into the first cleaning vessel 410, the cleaning liquid CL in the first cleaning vessel 410 may overflow to the outside of the first cleaning vessel 410. For example, the cleaning liquid CL may overflow to the second cleaning vessel 420 or spatter up to the vertical arms 130 of the transfer head 100.

Next, the transfer head 100 may pick up the completely held substrate “W”. For example, the transfer head 100 may elevate the substrate “W” in the opposite direction to the second direction D2 as illustrated in FIG. 18B. In this case, some of the residual cleaning liquids CL that remain on the transfer head 100 may flow out along the vertical arm 130 of the transfer head.

For example, the cleaning liquid CL that remains on the transfer head 100 may flow out from an inner surface of the vertical arm 130 to an outer surface of the vertical arm 130 along the inclined surface of the vertical arm 130. Furthermore, the cleaning liquid CL may flow out from the inner surface of the grasper 150 to the outer surface of the grasper 150 along the inclined direction of the upper surface of the grasper 150. Accordingly, a phenomenon in which the substrate “W” is reversely contaminated by the cleaning liquid CL, may be prevented. As a result, the cleanliness of the cleaning process may be improved.

The transfer head according to an embodiment may prevent reverse contamination of a semiconductor substrate.

The semiconductor manufacturing apparatus including the transfer head according to an embodiment may prevent reverse contamination of a semiconductor substrate.

Although an embodiment of the present disclosure has been described for illustrative purposes, those skilled in the art will appreciate that various modifications, and substitutions are possible, without departing from the scope and spirit of the present disclosure as disclosed in the accompanying claims.

Accordingly, the technical scope of the present disclosure is not limited to the detailed description of this specification, but should be defined by the claims.

What is claimed is:

1. A transfer head comprising:
a horizontal body extending in a first direction;
vertical arms connected to opposite peripheral portions of the horizontal body, respectively, the vertical arms extending in parallel to each other in a second direction perpendicular to the first direction, and each of the vertical arms having a side surface facing inward; and
graspers connected to lower ends of the vertical arms, respectively, and the graspers configured to hold a substrate,
wherein each of the vertical arms has a thickness in a third direction perpendicular to the first and second directions, and
wherein, for each vertical arm of the vertical arms, the thickness in the third direction decreases in a direction extending from an inner surface of the vertical arm to an outer surface of the vertical arm.

2. The transfer head of claim 1, wherein, for each vertical arm of the vertical arms, the minimum thickness of an intermediate portion of the vertical arm in the third direction is greater than the minimum thickness of a lower end portion of the vertical arm in the third direction.

3. The transfer head of claim 1, wherein, for each grasper of the graspers, a distance from the lowermost end of the grasper to an upper surface of the grasper decreases in a direction extending from the inner surface of the grasper to an outer surface of the grasper.

4. The transfer head of claim 1, wherein the horizontal body includes:
a lower plate extending in the first direction; and
a vertical plate extending upward from an upper surface of a first peripheral portion of the lower plate,
wherein the vertical arms are connected to a lower end of a second peripheral portion of the lower plate, and
wherein the second peripheral portion is located opposite the first peripheral portion in the third direction.

5. The transfer head of claim 1, wherein the vertical arms are integrally connected to the horizontal body.

6. The transfer head of claim 1, wherein each of the graspers includes:
a holding portion comprising a holding surface having a shape corresponding to a periphery of the substrate; and
a support portion extending from one side portion of the holding portion, and configured to support the substrate,
wherein the holding portion and the support portion are configured to accommodate the substrate.

7. The transfer head of claim 6, wherein a lower end of the holding portion is higher than a lower end of the support portion relative to a lower end of the transfer head, and
wherein a distance between lowermost ends of a holding portion of a first grasper of the graspers and a holding portion of a second grasper of the graspers facing the holding portion of the first grasper is smaller than a diameter of the substrate.

8. The transfer head of claim 6, wherein a maximum distance between the holding surface of a first grasper among the graspers and the holding surface of a second grasper among the graspers facing the first grasper is greater than a diameter of the substrate, and
a distance between lowermost ends of the first grasper and the second grasper is smaller than the diameter of the substrate.

9. The transfer head of claim 1, wherein a maximum thickness of the graspers in the third direction is greater than the thickness of the vertical arms.

10. The transfer head of claim 1, wherein each of the vertical arms is integrally connected to a corresponding one of the graspers.

11. The transfer head of claim 1, wherein each vertical arm of the vertical arms has a recess extending upward from a lower surface of the vertical arm,
wherein each grasper of the graspers includes a protrusion protruding upward from an upper surface of the grasper and coupled in the recess of a respective one of the vertical arms, and
wherein each grasper of the graspers is detachable from a corresponding vertical arm of the vertical arms.

12. The transfer head of claim 11, wherein, for each vertical arm, the recess extends from the inner surface of the vertical arm toward the outer surface of the vertical arm, and the recess is spaced apart from the outer surface of the vertical arm.

13. The transfer head of claim 1, wherein the horizontal body, the vertical arms, and the graspers form an inverted “U” shape.

14. A transfer head comprising:
a horizontal body extending in a first direction;
vertical arms connected to opposite peripheral portions of the horizontal body, respectively, the vertical arms extending in parallel to each other in a second direction perpendicular to the first direction, and each of the vertical arms having a side surface facing inward; and
graspers that are connected to lower ends of the vertical arms, respectively, and the graspers configured to hold a substrate,
wherein a lower end portion of each of the vertical arms has a first thickness in a third direction perpendicular to the first and second directions,
wherein an upper end portion of each of the graspers has a second thickness in the third direction,
wherein the second thickness is greater than the first thickness, and
wherein, for each grasper of the graspers, an upper surface of the grasper has a downward inclination from an inner surface of the grasper toward an outer surface of the grasper.

15. The transfer head of claim 14, wherein, for each vertical arm of the vertical arms, a thickness of the vertical arm in the third direction decreases in a direction extending from the inner surface of the vertical arm towards the outer surface of the vertical arm, and
wherein, for each vertical arm of the vertical arms, a minimum thickness of an intermediate portion of the vertical arm in the third direction is greater than a minimum thickness of a lower end portion of the vertical arm in the third direction.

16. A semiconductor manufacturing apparatus comprising:
a transfer head configured to hold a substrate;
a horizontal arm connected to an upper end of the transfer head;
a vertical driving shaft connected to a first side of the horizontal arm, and the vertical driving shaft being configured to move in a first direction, a second direction perpendicular to the first direction, and a third direction perpendicular to the first and second directions; and
a first cleaning module configured to hold a cleaning liquid,
wherein the transfer head includes:
a horizontal body extending in the first direction;
vertical arms connected to opposite peripheral portions of the horizontal body, respectively, the vertical arms extending in parallel to each other in the second direction, and each of the vertical arms having a side surface facing inward; and
graspers connected to lower ends of the vertical arms, respectively, and configured to accommodate the substrate,
wherein each of the vertical arms has a thickness in the third direction, and
wherein, for each vertical arm of the vertical arms, the thickness of the vertical arm in the third direction decreases in a direction extending from an inner surface of the vertical arm to an outer surface of the vertical arm.

17. The semiconductor manufacturing apparatus of claim 16, wherein the first cleaning module includes:
a first cleaning vessel configured to hold the cleaning liquid;
an ultrasonic wave generator provided on a bottom surface of the first cleaning vessel, and configured to generate ultrasonic waves; and
a second cleaning vessel configured to accommodate the first cleaning vessel, and to hold the cleaning liquid overflowing from the first cleaning vessel.

18. The semiconductor manufacturing apparatus of claim 16, wherein the horizontal body is configured to be positioned above the cleaning liquid when the substrate is held by the transfer head in the first cleaning module.

19. The semiconductor manufacturing apparatus of claim 16, wherein the transfer head is configured to cause the cleaning liquid to flow outward from inner surfaces of the vertical arms to outer surfaces of the vertical arms along an inclined surface of each of the vertical arms when the substrate is picked up from the first cleaning module by the transfer head and the vertical driving shaft.

20. The semiconductor manufacturing apparatus of claim 16, further comprising:
a second cleaning module including a brush; and
a third cleaning module configured to dry the substrate.
